(19) United States
(12) Patent Application Publication
(10) Pub. No.: US 2008/0099334 A1
(43) Pub. Date: May 1, 2008

(54) GAS SENSOR WITH INCREASED RELIABILITY AND RELATED MANUFACTURING METHOD

(75) Inventor: Masanobu YAMAUCHI, Kariya-si (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 11/926,352

(22) Filed: Oct. 29, 2007

(30) Foreign Application Priority Data
Oct. 30, 2006 (JP) 2006-294299

(51) Int. Cl. G01N 27/26; H05K 7/00

(52) U.S. Cl. 204/427; 29/592.1

(57) ABSTRACT

A gas sensor and a related manufacturing method are disclosed. The gas sensor includes a detecting unit comprised of a concentration detecting element, composed of a solid electrolyte body having inner and outer walls formed with electrodes, a housing, output terminals and a heater, and an output extracting unit comprised of at least signal wires, power conducting wires, output extracting terminals, power conducting terminals, an insulator and a casing. The detecting unit and the output extracting unit are united to each other in the insulator such that the output terminals, holding a base body of the heater in electrical insulation, and the output extracting terminals are conducted to each other and the heater electrodes and the power conducting terminals are conducted to each other upon which a boss portion of the housing is fixedly fitted to a leading end portion of the casing.

### CROSS REFERENCE TO RELATED APPLICATIONS

This application is related to Japanese Patent Application No. 2006-294299, filed on Oct. 30, 2006, the content of which is hereby incorporated by reference.

### BACKGROUND OF THE INVENTION

1. Technical Field of the Invention

The present invention relates to structures of gas sensors, each operative to detect a concentration of specified gas in exhaust gases emitted form, for instance, automotive engines or the like, and related manufacturing methods and, more particularly, to a cup-shaped gas sensor and a related manufacturing method.

2. Description of the Related Art

In related art, attempts have heretofore been made to provide gas sensors each installed on an exhaust gas flow passage of an internal combustion engine such as an automotive engine or the like with a view to detecting a concentration of specified gas component for calculating an air/fuel ratio based on the detected specified gas concentration for thereby performing a combustion control of the internal combustion engine.

For one of these gas sensors, an oxygen sensor or the like has been widely used which includes an oxygen concentration detecting element composed of a bottomed cylindrical solid electrolyte body made of oxygen ion conductive material such as zirconia or the like and having inner and outer walls formed with electrode layers made of platinum or the like, a heater inserted to an inside of the oxygen concentration detecting element for heating the same, output extracting means extracting an output from the oxygen concentration detecting element to the outside thereof, and power conducting means through which electric power is supplied to the heater.

Meanwhile, with an increasing competition on pricing in a modern automotive industry, it has been an important key factor for reduction of production cost to develop a sensor structure and a related manufacturing method to be advantageous for achieving reduction in the number of component parts and simplification of assembling steps in the gas sensor of this kind.

For instance, U.S. Pat. No. 7,032,433 discloses a gas sensor, having an increased reliability and an ease of production, and a related manufacturing method. As shown in FIG. 13A representing a reprint of FIG. 2 of this U.S. patent, there is shown the gas sensor 1 that includes an oxygen sensing element 2, a main metal fitting 3 for holding the gas sensing element 2, one or more sensor terminal fittings 16, 17 extending from the gas sensing element 2 on a rear side thereof, a metallic outer sleeve 21 having an own leading end connected to the main metal fitting 3, and an electrically insulating separator 31, accommodated inside the metallic outer sleeve 21, which has a flange portion 34 formed with an abutting surface 34a. The metallic outer sleeve 21 has a flange abutting surface 24b, available to be brought into abutting engagement with the outer sleeve abutting surface 34a, which has a sloped surface that radially expands toward a leading end to allow the separator 31 to be held with the metallic outer sleeve 21 with the separator 31 being urged rearward.

The manufacturing method, disclosed in such a related art, can prevent various deficiencies such as the rupturing of the concentration detecting element and the breakdown of sensor terminal members caused by the sensor terminal members per se or a stress occurring between the sensor terminal members and the concentration detecting element due to displacements in position or attitude of the sensor terminal members.

With the gas sensor 1 disclosed in such a related art, further, a heater 15 including a bar-like ceramic heater is employed as shown in FIG. 13B showing a reprint of FIG. 4 of the above-mentioned U.S. patent. The heater 15 is composed of a core member principally made of alumina and formed with a heating portion 15a having a resistance heating element. The heater 15 has a rear end formed with electrode pads 15e, 15f to which heater terminal fittings 16, 17 and heater lead wires 18, 19 are connected by brazing. With the heater 15 being supplied with electric power through these components, a leading end portion of the oxygen concentration detecting element 2 is heated. The heater terminal fitting 17 includes a connector portion 17a that clamps core wires of a heater lead wire 18 for providing an electrical connection between the heater terminal fitting 17 and the heater lead wire 18.

As shown in FIGS. 13C and 13D representing reprints of FIGS. 7 and 8 of the above-described U.S. patent, therefore, first and second sensor terminal fittings 11,12 for extracting a signal from the sensing element 2, the heater 15 and the heater lead wires 18, 19 are not connected to the sensing element 2. In assembly, these component parts are assembled to the separator 31 in advance to be accommodated inside the metallic sleeve 21. Thereafter, the heater 15 is inserted to the sensing element 2, thereby alleviating stress acting on a connected portion between the heater 15 and the sensor terminal fittings 11, 12 for preventing the fold-down cracking of the heater 15 during an assembly thereof and the rupturing of connected portions of sensor output lead wires 13, 14.

Another attempt has heretofore been made to provide an oxygen sensor as disclosed in Japanese Patent Application Publication No. 2000-193629. In this related art, the oxygen sensor includes a cover member, having ventilating apertures for introducing atmospheric air as reference gas, to which a ceramic separator and connector fittings are assembled in advance. In assembly, the cover member is installed in a casing, to which a sensing element is preassembled, making it possible to permit the insertion of and installation of the connector fittings to the sensing element.

With the gas sensor of the related art structure and the related manufacturing method disclosed in U.S. Pat. No. 7,032,433, the heater terminal fittings 16, 17 are brazed to the heater electrode pads 15c, 15f. Therefore, the heater 15 is compelled not to be provided on the sensing element 2 but to be provided on the separator 31 as shown in FIG. 13C. During an assembly of inserting the heater 15 into the sensing element 2 as shown in FIG. 13D, a specified chucking mechanism CH needs to be used for inserting the heater 15 while clamping the same for the purpose of preventing a damage to the heater 15, resulting in a complicated assembling process.

Like the heater 15, the sensor terminal fittings 11, 12 are similarly connected not to the sensing element 2 but to the separator 31. Under such a situation, the sensor terminal fittings 11, 12 are fixedly secured onto the separator 31 via the lead wires 13, 14 at connecting portions 11a, 12a extending from the lead wires 13, 14 and merely supported with the separator 31 at the separator abutting portions 11b, 12b in a is resilient manner.

Meanwhile, an inserting portion 11c of the first sensor fitting 11 is inserted to a bottomed bore 2a of the oxygen sensor 2 in pressured contact therewith for ensuring an electrical connection with a sensor internal electrode 2c. Therefore, it is conceived that during such an inserting step, the inserting portion 11c encounters a relatively large frictional force.

Further, an inserting portion 12c of the second sensor fitting 12 is formed in a smaller inner diameter than an outer diameter of the sensing element 2 to resiliently hold the sensing element 2. It is also conceived that during a step of inserting the second sensor fitting 12 into the sensing element 2, the inserting portion 12c encounters a relatively large frictional force.

In an attempt to assemble the sensor terminal fittings 11, 12 to the sensing element 2, the presence of the frictional forces result in increases in resistance forces. Thus, buckling occur on weakened rigidity portions of the lead wires 13, 14 in areas with no sheath at positions immediately above the connector portions 11a, 12a of the lead wires 13, 14, causing breakdowns to occur.

In an alternative, it is considered that for the purpose of preventing the occurrence of such buckling, the connecting portions of the sensor fittings 13, 14 need to have weakened urging forces to allow the sensor fittings 11, 12, suspended from the lead wires 13, 14, to be easily inserted to the oxygen sensor 2.

Accordingly, there is a fear of incomplete contact in electrical connection between the sensor fittings 11, 12 and the inner and outer electrodes 2c, 2f of the sensing element.

Further, the sensor terminal fittings 11, 12 covered with the metallic outer sleeve 21, no mounting statuses of the sensor terminal fittings 11, 12 can be observed and it is hard to confirm whether or not the sensor terminal fittings 11, 12 are normally mounted on the sensing element 2.

Furthermore, the heater 15 is assembled to the separator 31 and the sensing element 2 is assembled to the main metallic fitting 3 without mounting the sensor terminal fittings 11, 12. Therefore, no evaluation can be made to confirm the function and quality of the sensing element 2 while activating the heater 15 to heat the same. That is, the evaluation on the sensing element 2 should be conducted with the cover member 21 installed on the casing 3, to which the sensing element 2 is preassembled, in a nearly completed status.

In addition, the sensor terminal fittings 11, 12 are fitted under a status with the sensing element 2 assembled to the main metallic fitting 3. As a result, the sensing element 2 has areas, to which the sensor terminal fittings 11, 12 are connected, which are exposed from the main metallic fitting 3, causing an increase in a physical size of the sensing element 2.

With the oxygen sensor of the latter related art mentioned above, moreover, the heater and the sensor connector fittings are mounted on the cover member and the sensing element is mounted on the casing with no installation of the sensor connector fittings. Thus, the sensor connector fittings cannot be pushed into and mounted on the sensing element if the cover member is concurrently mounted to the casing.

Accordingly, a functional evaluation of the sensing element cannot be accomplished during a manufacturing process like the gas sensor of the former related art.

With the gas sensors of the structures, mentioned above, and the manufacturing methods of the related arts, further, a difficulty is encountered in confirming a ventilating ability of the atmospheric air introducing portion for introducing atmospheric air as reference gas in the presence of the heater being assembled.

### SUMMARY OF THE INVENTION

The present invention has been completed with a view to addressing the above issues and has an object to provide a gas sensor, which is easy to be assembled and has a structure with increased reliability enabling to inspect a function and quality such as a ventilating property of an atmospheric air introducing section, an insulating property of a signal extracting section and a response and sealing property of a concentration detecting element during a process of manufacturing the gas sensor, and a related manufacturing method.

To achieve the above object, a first aspect of the present invention provides a cup-shaped gas sensor having a concentration detecting element composed of an ion conductive solid electrolyte body, formed in a bottomed cylindrical structure with a closed leading end, which has an inner wall, formed with a reference electrode layer available to be held in contact with reference gas, and an outer wall, formed with a measuring electrode layer available to be held in contact with measuring gases for detecting a concentration of a specified gas in the measuring gases. The gas sensor comprises: a detecting unit composed of at least the concentration detecting element, a housing fixedly supporting the concentration detecting element in a measuring gas flow passage, a pair of output terminals comprised of a reference electrode output terminal, extending from the reference electrode layer, and a measuring electrode output terminal, extending from the measuring electrode layer, and a heater, composed of an insulating base body internally having a heating element, which has a pair of heater electrodes formed on a surface of the insulating base body and connected to the heating element for generating a heat when supplied with electric power; and an output extracting unit including at least a pair of signal wires connectable to an external controller, a pair of output extracting terminals connected to the pair of signal wires, respectively, a pair of power conducting terminals connected to the pair of power conducting wires, an insulator holding the pair of output extracting terminals and the pair of power conducting terminals in insulating capability, an insulator holding the pair of output extracting terminals in insulating capability, a substantially cylindrical casing protecting the insulator, a sealing member disposed in the housing at a base end portion thereof for sealing the pair of signal wires and the pair of power conducting terminals in insulating capability, and a ventilating section introducing atmospheric air to an inside of the easing. The reference electrode output terminals and the measuring electrode output terminals clamp a part of the insulating base body of the heater as an insulating support member for ensuring an insulation between the reference electrode output terminals and the measuring electrode output terminals. The insulator has heater insertion bores within which the output terminals and the output extracting terminals are electrically conducted to each other while the heater electrode and the power conducting terminal are electrically conducted to each other. The detecting unit and the output extracting unit are united to each other.

With the gas sensor of the first aspect of the present invention, an evaluation can be conducted to independently inspect the detecting unit and the output extracting unit before these component parts being assembled, enabling deficiency to be found on a manufacturing stage. This avoids waste of materials while enabling a remarkable increase in reliability of the gas sensor as a completed article.

Further, the pair of output terminals clamp the heater on both sides thereof with the heater placed in a stabilized placement position. This prevents the occurrence of bad electrical contact between the power conducting terminals and the heater electrodes due to misalignment in position of the heater. In addition, the heater has an insulating base body that ensures insulating properties of the output terminals, causing no fear of occurrence in short-circuiting of the output terminals.

Furthermore, the output terminals are electrically connected to the output extracting terminals, fixedly secured to the insulator, in the insulator, causing no fear of disconnection occurring due to vibrations applied form an external source. Accordingly, the gas sensor can have increased reliability as a completed article.

With the gas sensor of the present embodiment, the reference electrode output terminal and the measuring electrode output terminal may preferably have concaved walls, formed in circular-arc shapes in cross section, respectively, which are held in tight contact with a side periphery of the insulating base body of the heater.

With the gas sensor of such a structure, the reference electrode terminal and the measuring electrode terminal grasp the heater so as to enwrap the same, thereby restricting the heater from moving in radiated directions. This allows the heater to be kept in a further stabilized mounting position, enabling a further increase in reliability of the gas sensor.

With the gas sensor of the present embodiment, the output extracting terminals may preferably include spring terminals, each made of resilient metallic material and formed in a substantially “J”-shape configuration, which are resiliently held in electrical contact with the output terminals, respectively.

With the gas sensor of such a structure, the output terminals and the output extracting terminals are resiliently connected to each other, providing increased vibration proof. Thus, no disconnection occurs in each of these component parts due to vibrations of a vehicle.

Further, the output terminals have the circular arc contact surfaces in cross section and the output extracting terminals have the flat surfaces in cross section. Thus, even if an assembling position of any of the terminals is dislocated from a center, the relevant terminals can be surely kept in point contact at one point, causing the both terminals to be held in electrical contact with each other in a highly reliable manner. Accordingly, the gas sensor can have further increased reliability.

With the gas sensor of the present embodiment, the power conducting terminals may preferably include spring terminals, each made of resilient metallic material and formed in a substantially “J”-shape configuration, which are resiliently held in electrical contact with the heater electrodes, respectively.

With the gas sensor of such a structure, the power conducting terminals are resiliently held in pressurized contact with the heater electrodes with the heater electrodes and the power conducting terminals being held in tight contact with each other. Therefore, even if the vibrations of the vehicle are applied to the heater electrodes and the power conducting terminals, the electrical connections are ensured at all times.

A second aspect of the present invention provides a method of manufacturing a cup-shaped gas sensor having a concentration detecting element composed of an ion conductive solid electrolyte body, formed in a bottomed cylindrical structure with a closed leading end, which has an inner wall, formed with a reference electrode layer available to be held in contact with reference gas, and an outer wall, formed with a measuring electrode layer available to be held in contact with measuring gases for detecting a concentration of a specified gas in the measuring gases. The method comprises the steps of: forming a detecting unit including the steps of holding a heater, operative to generate a heat when supplied with electric power, in the concentration detecting unit via a reference electrode fitting having a reference electrode output terminal, a reference electrode connecting portion and a heater clamping portion, mounting a measuring electrode fitting having a measuring electrode output terminal and a measuring electrode connecting portion onto the measuring electrode layer, inserting the concentration detecting element into a substantially cylindrical housing via a fixing member for thereby forming the detecting unit including at least a pair of output terminals, composed of the reference electrode output terminal and the measuring electrode output terminal, the heater and the housing wherein the output terminals and a pair of heater electrodes, formed on a surface of the heater, are exposed to an upper area of the housing and the pair of output terminals clamp the heater; forming an output extracting unit including the steps of mounting a pair of output extracting terminals and a pair of power conducting terminals into an insulator, connecting a pair of signal wires to the pair of output terminals, respectively, connecting a pair of power conducting wires to the pair of power conducting terminals, respectively, inserting the pair of signal wires and the pair of power conducting wires into the insulator in a plurality of insertion bores formed therein, and accommodating the insulator in a substantially cylindrical casing for thereby forming the output extracting unit including at least the signal wires, the power conducting wires, the output extracting terminals, the power conducting terminals, the insulator and the casing; forming output extracting terminals including the step of forming the output extracting terminals and the power conducting terminals in spring-like terminals formed in substantially “J”-shaped configurations having flat shapes in cross section using a resilient metallic material; and assembling the gas sensor including the steps of inserting the detecting unit into the output extracting unit to cause the output terminals and the output extracting terminals and the heater electrodes and the power conducting terminals to be conducted to each other within the insertion bores formed in the insulator for thereby completing an assembly of the gas sensor.

With the manufacturing method of the second aspect of the present invention, the detecting unit and the output extracting unit can be assembled independently of each other in separate manners. In assembling the detecting unit, further, a whole of the component parts are assembled in sequence in a simplified process with centers of all the component parts being coaxially placed. This provides an extremely ease of achieving the rationalization in assembling the detecting unit.

A part of the base body of the heater can be used as an area for ensuring insulation between the measuring electrode terminal and the reference electrode terminal. In addition, the measuring electrode terminal and the reference electrode terminal hold the heater in a stabilized mounting position, providing extremely remarkable rationalization.

Further, using the reference electrode fitting allows the heater to be fixedly secured while, at the same time, making it possible to hold the reference electrode terminal, providing extremely remarkable rationalization.

In addition, during a step of assembling the output extracting unit, there is no need for the heater to be held in manners like those of the gas sensors of the related arts and the step of assembling the output extracting unit can be accomplished through mere efforts of inserting and pressure bonding the component parts. This provides extremely remarkable rationalization in assembly.

Furthermore, during steps of assembling the detecting unit and the output extracting unit, the heater is assembled to the concentration detecting element in a stabilized fixing state and the heater is inserted with the output extracting unit and the power conducting terminals being resiliently flexed. Thus, no extra force acts on the heater and no fear occurs for the heater to be damaged during assembly. Moreover, the output extracting unit serves as a guide for the heater to be inserted during the insertion thereof.

Accordingly, this makes it extremely easy to rationalize the steps of assembling the detecting unit and the output extracting unit.

The reference electrode connecting portion and the measuring electrode connecting portion can be accommodated in the housing. This provides no need for the connecting areas between the concentration detecting element and the reference electrode connecting portion and the measuring electrode connecting portion to be exposed from the housing, enabling a reduction in size of a physical body of the gas sensor.

With the second aspect of the present invention, the manufacturing method may preferably further comprise the step of forming the output terminals including the steps of making the pair of output terminals using a resilient metallic material, and forming the output terminals in concaved walls, held in abutting contact with a surface of the heater, each of which has a circular-arc shape in cross section facing the heater.

With the manufacturing method of the second aspect of the present invention, the output terminals are held in tight contact with the heater while resiliently pressurizing the heater, causing the output terminals to have increased restricting force for the heater.

The output terminals and the heater are associated to restrict each other and the both component parts can be located in stabilized positions. Thus, there is no fear of deformations occurring in the output terminals and dislocation occurring in position of the heater during the steps of assembling the detecting unit and the output extracting unit, providing an ease of assembly.

Thus, according to the first and second aspects of the present invention, there is provided a gas sensor, which is easy to be assembled and has a structure with increased reliability enabling to inspect a function and quality such as a ventilating property of an atmospheric air introducing section, an insulating property of a signal extracting section and a response and sealing property of a concentration detecting element during a process of manufacturing the gas sensor.

### BRIEF DESCRIPTION OF THE DRAWINGS

FIG. 1A is a cross sectional view of a gas sensor of a first embodiment according to the present invention.

FIG. 1B is a cross sectional view taken on line A0-A0 of FIG. 1A.

FIGS. 2A to 2D are views showing a method of manufacturing a detecting unit with FIG. 2A representing a perspective view of a detecting unit forming a part of the gas sensor shown in FIGS. 1A and 1B, FIG. 2B representing an exploded view of the detecting unit shown in FIG. 2A, FIG. 2C representing a cross section of the detecting unit shown in FIG. 2A with a lower end portion of a housing being caulked and FIG. 2D representing a cross section of the detecting unit shown in FIG. 2A with an upper end portion of the housing being caulked.

FIGS. 3A to 3C are cross sectional views showing a method of manufacturing an output extracting unit forming another part of the gas sensor shown in FIGS. 1A and 1B with FIG. 3A representing an exploded cross section of the output extracting unit in an initial stage on production, FIG. 3B representing a cross section of the output extracting unit in an intermediate stage on production and FIG. 3C representing a cross section of the output extracting unit in a final stage on production.

FIGS. 4A and 4B are cross sectional views showing a method of assembling the detecting unit and the output extracting unit to form the gas sensor of the present embodiment with FIG. 4A representing a cross section showing a stage before the detecting unit and the output extracting unit are assembled and FIG. 4B representing a cross section showing another stage after the detecting unit and the output extracting unit are assembled.

FIG. 5 is an exploded perspective view showing an insulator, power conducting terminals and output extracting terminals forming output extracting means constituting the gas sensor of the first embodiment according to the present invention.

FIGS. 6A and 6B are cross sectional views showing details of the insulator and the output extracting terminals and power conducting terminals assembled to the insulator with FIG. 6A representing a cross section of the insulator to which the output extracting terminals and the power conducting terminals are assembled and FIG. 6B representing a cross section taken on line 6B-6B of FIG. 6A.

FIG. 6C is a bottom view of the insulator as viewed in a direction as shown by an arrow C-C of FIG. 6B.

FIG. 6D is a cross section taken on line 6D-6D of FIG. 6A.

FIGS. 7A to 7F are cross sectional views showing details of the insulator, the output terminals and power conducting terminals for illustrating effects of the gas sensor of the first embodiment with FIG. 7A representing a cross section of the insulator in a state just before the output terminals are brought into abutting engagement with tapered guide portions of the insulator, FIG. 7B representing the insulator in a state under which the output terminals penetrate between sloped portions of the output terminals and protrusions of the insulator, FIG. 7C representing the insulator in a state under which the output terminals are placed in correct positions between the sloped portions of the output terminals and the protrusions of the insulator; FIG. 7D representing a cross section illustrating a first step of assembling a heater to the power conducting terminals fixed in the insulator, FIG. 7E representing a cross section illustrating a second step of assembling the heater to the power conducting terminals fixed in the insulator and FIG. 7F representing a cross section illustrating a final step of assembling the heater to the power conducting terminals fixed in the insulator.

FIGS. 8A and 8B are cross sectional views showing effects of the gas sensor of the first embodiment according to the present invention with FIG. 8A representing a cross section taken on line 8A-8A in FIG. 7C and FIG. 8B representing a cross section taken on line 8B-8B in FIG. 7C.

FIGS. 9A and 9B are conceptual views showing exemplary evaluating inspections being carried out on the detecting unit and the output extracting unit in the course of productions thereof with FIG. 9A representing a method of inspecting the detecting unit and FIG. 9B representing a method of inspecting the output extracting unit.

FIG. 10A is a perspective view showing a reference electrode fitting forming a part of a gas sensor of a second embodiment according to the present invention.

FIG. 10B is a cross sectional view showing the reference electrode fitting shown in FIG. 10A.

FIG. 11A is a perspective view showing a measuring electrode fitting forming a part of a gas sensor of a third embodiment according to the present invention.

FIG. 11B is a cross sectional view showing the measuring electrode fitting shown in FIG. 11A.

FIG. 12A is a perspective view showing a reference electrode fitting forming a part of a gas sensor of a fourth embodiment according to the present invention.

FIG. 12B is a fragmentary cross sectional view showing a detecting unit incorporating the reference electrode fitting shown in FIG. 12A.

FIG. 12C is a fragmentary cross sectional view showing the detecting unit incorporating the reference electrode fitting shown in FIG. 12A.

FIG. 13A is a cross sectional view showing an overall structure of a gas sensor of a related art structure.

FIG. 13B is an exploded perspective view showing a status in which an oxygen sensor element and a heater assembled to a separator in the oxygen sensor of the related art structure.

FIG. 13C is a cross sectional view showing a status under which a separator, internally retaining sensor terminal fittings, is placed in a metallic outer sheath.

FIG. 13D is a cross sectional view showing how a heater is guided and inserted to a rear end opening of an oxygen sensor element in the oxygen sensor of the related art structure.

### DETAILED DESCRIPTION OF PREFERRED EMBODIMENTS

Now, gas sensors of various embodiments and a related manufacturing method according to the present invention will be described below in detail with reference to the accompanying drawings. However, the present invention is construed not to be limited to such embodiments described below and technical concepts of the present invention may be implemented in combination with other known technologies or the other technology having functions equivalent to such known technologies.

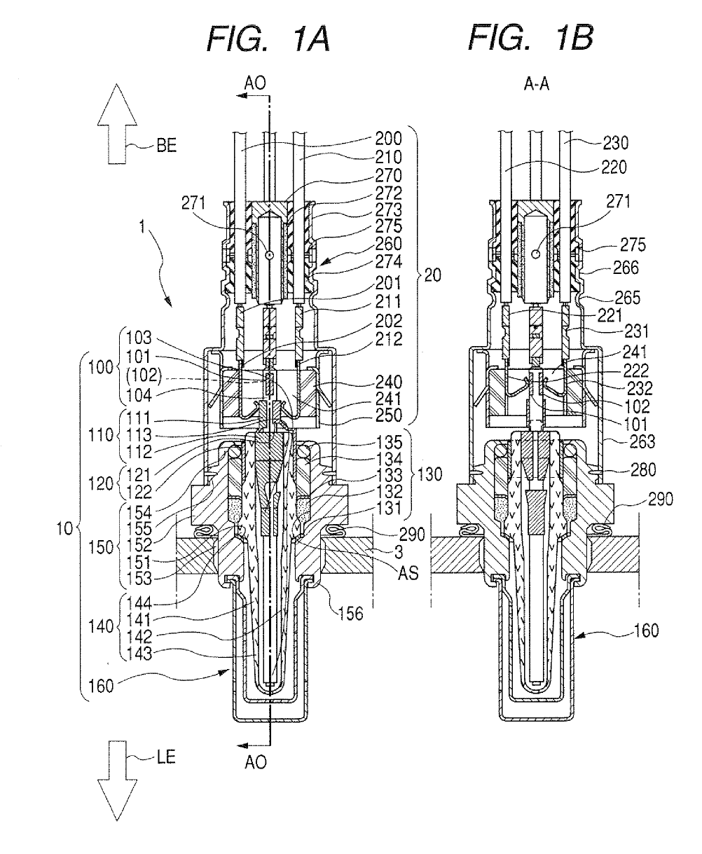

In the following description, it will be appreciated that a gas sensor of the present embodiment has an upper end portion representing a base end portion oriented in a direction designated by an empty arrow BE and a lower end portion representing a leading end portion oriented in the other direction designated by an empty arrow LE in FIGS. 1A and 1B. This applies to gas sensors of other embodiments implementing the present invention.

In the following description, further, it is to be understood that such terms as “inner, “outer”, “inside”, “outside”, “inward”, “outward”, “upper”, “lower”, “radial”, “axial”, “coaxial”, “axially”, “parallel”, “toward”, “opposite”, “away”, “laterally” and the like are words of convenience and are not to be construed as limiting terms.

### First Embodiment

A gas sensor of a first embodiment according to the present invention will be described below in detail with reference to the accompanying drawings.

FIG. 1A is a cross sectional view showing an overall structure of the gas sensor of the first embodiment according to the present invention. FIG. 1B is a cross sectional view taken on line A0-A0 of FIG. 1A.

As shown in FIGS. 1A and 1B, the gas sensor 1 generally includes a detecting unit 10 and an output extracting unit 20 oriented in a leading end LE and a base end BE, respectively.

The detecting unit 10 includes a concentration detecting element 140, a heater 100 disposed inside the concentration detecting element 140 and operative to generate a heat upon receipt of electric power, a housing 150 fixedly supporting the concentration detecting element 140 in a measuring gas flow passage, a pair of output terminal fittings 110, 120 extending from the concentration detecting element 140 to be exposed from the housing 150 for grasping the heater 100, a fixing member 130 interposed between the concentration detecting element 140 and the housing 150, and a cover body 160 covering a leading end portion 140a of the concentration detecting element 140.

The concentration detecting element 140 includes a solid electrolyte body 141, formed in a bottomed cylindrical shape and having a closed leading end 141a, which is made of an oxygen ion conducting material such as zirconia or the like. The solid electrolyte body 141 has an inner wall, formed with a reference electrode layer 142, and an outer wall formed with a measuring electrode layer 143. The solid electrolyte body 141 has an intermediate area formed with a large-diameter annular solid electrolyte engaging portion 144.

The pair of output terminal fittings 110, 120 includes a reference electrode fitting 110 and a measuring gas electrode fitting 120. The reference electrode fitting 110 includes a reference electrode output terminal 111, a reference electrode connecting portion 112 and a heater clamping portion 113. The measuring gas electrode fitting 120 includes a measuring electrode output terminal 121 and a measuring electrode connecting portion 122.

The reference electrode output terminal 111 and the measuring electrode output terminal 121 form the pair of output terminals.

The heater 100 includes a heater base body 104, made of ceramic material such as alumina or the like in the form of an elongated shaft, which has a leading end internally incorporating a heating element 103. The heating element 103 has a base end having an outer circumferential surface formed with a pair of heater electrodes 101, 102 in electrical connection with the heating element 103 through a pair of lead wires (not shown).

The heater 100 is inserted to the concentration detecting element 140 and resiliently fixed with the heater clamping portion 113.

The concentration detecting element 140 has an inside to which the reference electrode fitting 110 extends to provide an electrical connection between the reference electrode layer 142 and the reference electrode connecting portion 112.

The concentration detecting element 140 has an outside to which the measuring electrode connecting portion 122 is fitted to provide an electrical connection between the measuring electrode layer 143 and the measuring electrode connecting portion 122

The heater 100, inserted to the inside of the concentration detecting element 140, has a first base portion resiliently fixed with the heater clamping portion 113 and a second base end portion resiliently clamped with the reference electrode output terminal 111 and the measuring electrode terminal 121 at a position exposed axially outward from the concentration detecting element 140.

The housing 150 includes a housing body 152, which is internally formed with a large diameter bore 152a, an intermediate diameter bore 152b and a small diameter bore 152c in this order from an upper area toward a lower area of the housing body 152. A housing engaging portion 151 is formed in the form of an annular shoulder at a boundary between the intermediate diameter bore 152b and the small diameter bore 152c. The housing body 152 has a base end portion formed with an upper opening end portion 154 that serves as an upper caulking portion, a boss portion 155, and a leading end portion formed with a threaded portion 153 and a lower opening end portion 156 that serves as a lower caulking portion.

The annular solid electrolyte engaging portion 144 rests on the housing engaging portion 151 of the housing body 152 to be held in fitting engagement therewith via a metallic cushion member 131.

With the solid electrolyte body 141 disposed inside the housing 150, an annular space AS is provided between an outer circumferential wall of the solid electrolyte body 141 and an inner wall of the large diameter bore 152a of the housing body 152. The annular space AS has a lower annular portion filled with an insulating powder 132 such as, for instance, talc or the like, an intermediate annular portion in which an insulating compact body 133 is placed, and an upper annular portion filled with an insulating sealing member 134 made of insulating material such as, for instance, ceramic or glass or the like. The annular space AS has the uppermost area in which an elastic packing member 135 is placed in contact with an upper end face of the insulating sealing member 134. Thus, the metallic cushion member 131, the insulating powder 132, the insulating compact body 133, the insulating sealing member 134 and the elastic packing member 135 form a detecting-element fixing member 130. With the detecting-element fixing member 130 sub-assembled in such a structure, the upper caulking portion 154 is caulked at an uppermost end of the housing 150 to fixedly hold the concentration detecting element 140 in a unitary structure with the housing 150.

The output extracting unit 20 includes a pair of output extracting terminals 202, 212, a pair of signal wires 200, 210 connected to output extracting terminals 202, 212, respectively, a pair of power conducting terminals 222, 232, a pair of power conducting wires 220, 230 connected to the power conducting terminals 222, 232, respectively, an insulator 240, an insulator holder fitting 250, a casing 260, connector fittings 201, 211, 221, 231, a filter support member 270, a cylindrical water-shedding filter 272, and sealing members 273, 274 acting as an upper bush and a lower bush, respectively.

The output extracting terminals 202, 212 and the power conducting terminals 222, 232 are fixedly supported with the insulator 240 in insulating states. The output extracting terminals 202, 212 and the power conducting terminals 222, 232 have respective base ends whose end portions are exposed from the insulator 240 and connected to the respective signal wires 200, 210 and the power conducting wires 220, 230 via the connector fittings 201, 211, 221, 231.

The insulator 240 is internally formed with a substantially cross-shaped heater insertion bore 241.

The output extracting terminals 202, 212 and the power conducting terminals 222, 232, made of resilient metallic material, are formed in substantially “J”-shaped spring configurations. The output extracting terminals 202, 212 and the power conducting terminals 222, 232 have respective leading end portions, which are exposed to the heater insertion bore 241.

The output terminals 111, 121 and the output extracting terminals 202, 212 are resiliently connected to each other in the heater insertion bores 241. The heater electrodes 101, 102 and the power conducting terminals 222, 232 are also resiliently connected to each other in the heater insertion bores 241.

The insulator holder fitting 250 allows the insulator 240 to be resiliently fixed in the casing 260.

The casing 260 has a base end that is sealed with the sealing members 273, 274, acting as the upper bush and the lower bush, respectively, which are formed of elastic members. The sealing members 273, 274 support the signal wires 200, 210 and the power conducting wires 220, 230, connected to external components, in insulating effects.

Further, the sealing members 273, 274 are formed in substantially cylindrical shapes, respectively, and have central bores accommodating therein the filter support member 270 and the water-shedding filter 272 in fitting engagements.

The filter support member 270 has a bottomed cylindrical shape having a closed base end. The filter support member 270 has a sidewall formed with a plurality of laterally extending venting holes 271. The cylindrical water-shedding filter 272 is fitted to an outer circumferential periphery of the filter support member 270 so as to cover the same for permeating atmospheric air while blocking the flow of liquid. The water-shedding filter 272 is formed of a porous body made of resin such as, for instance, polytetrafluoroethylene (PTFE).

The sealing members 273, 274 have pluralities of sealing-member venting holes 275 formed at positions facing the support-member venting holes 271 for fluid communication therewith.

The casing has a leading end portion 263 held in fitting engagement with the boss portion 154 of the housing 250. The leading end portion 263 is fixedly secured to the boss portion 154 of the housing 250 by bonding means 280 formed by, for instance, laser welding or the like.

With such a structure mentioned above, the gas sensor 1 is mounted on a measuring gas flow passage wall 3 via a resilient member 290 such as a spring washer or the like upon screwing the threaded portion 153 onto the measuring gas flow passage wall 3 so as to allow the concentration detecting element 140 to be exposed to a measuring gas flow passage.

Now, a method of manufacturing the gas sensor 1 of the first embodiment according to the present invention will be described below in detail.

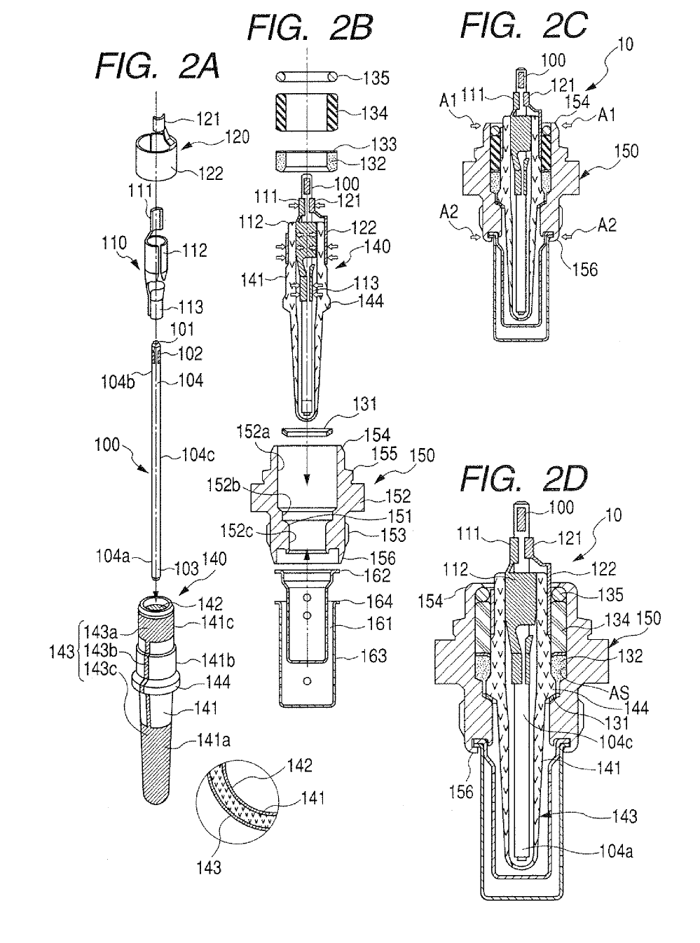

First, a method of manufacturing the detecting unit 10 will be described step by step with reference to FIGS. 2A to 2D.

As shown in FIG. 2A, first, the heater 100 is formed. To this end, the heater base body 104 is formed of ceramic material such as alumina or the like in an elongated rod. During the formation of such a heater base body 104, the heating element 103, composed of tungsten or the like (not shown), is incorporated in an inside of the heater base body 104 at a leading end portion 104a thereof. The heating element 103 is electrically corrected to the pair of heater electrodes 101, 102 through a pair of wire leads (not shown) axially extending through the heater base body 104. The heater base body 104 has a base end 104b formed with the pair of heater electrodes 101, 102. In such a way, the heater 100 is formed.

In forming the concentration detecting element 140, the solid electrolyte body 141 is made of oxygen ion conducting solid electrolyte material such as zirconia or the like and formed in a bottomed cylindrical structure with a leading end 141a being closed. The solid electrolyte body 141 has inner and outer walls formed with the porous reference electrode layer 142 and the porous measuring electrode layer 143, respectively, which are made of platinum or platinum alloy.

During such a forming step, as shown in FIG. 2A, the large-diameter annular solid electrolyte engaging portion 144 is formed on the solid electrolyte body 141 at the intermediate area 141b thereof. The measuring electrode layer 143 includes the solid electrolyte body 141 having the base end portion 141c, formed with a measuring electrode layer connector portion 143a surrounding an outer circumferential periphery of the base end portion 141c, the leading end portion 141a formed with a measuring electrode layer measuring portion 143c, and the intermediate portion 141b formed with a measuring electrode layer lead portion 143b for providing an electrical connection between the measuring electrode layer connector portion 143a and the measuring electrode layer measuring portion 143c.

The reference electrode fitting 110, made of resilient metallic material such as stainless steel or the like, is formed with the reference electrode output terminal 111, which has a circular arc shape in cross section that extends on a side toward a base end and is concaved toward an axial center, the reference electrode connecting portion 112 formed in a partially cutout sleeve (formed in a substantially C-shaped in cross section) which is slightly larger in diameter than an inner diameter of the concentration detecting element 140, and the heater clamping portion 113 formed in a partially cutout sleeve (formed in a substantially C-shaped in cross section) which is slightly smaller in diameter than that of the heater 100.

In clamping the heater 100, the heater clamping portion 113 is resiliently expanded in diameter and the leading end portion 104a of the heater 100 is inserted to and clamped with the heater clamping portion 113. Then, contracting the reference electrode connecting portion 112 in diameter allows both the heater 100 and the reference electrode connecting portion 112 to be inserted to the solid electrolyte body 141.

The measuring electrode fitting 120, made of resilient metallic material such as stainless steel or the like, is formed of the measuring electrode output terminal 121, which has a circular arc shape in cross section that extends toward a base end side and is concaved toward an axial center, and the measuring electrode connecting portion 122 formed in a partially cutout sleeve (formed in a substantially C-shaped in cross section) which is slightly smaller in diameter than an outer diameter of the base end portion 141c of the solid electrolyte body 141 forming the concentration detecting element 140.

Resiliently expanding the measuring electrode connecting portion 122 in diameter allows the measuring electrode connecting portion 122 to be inserted to and fitted to the base end portion 141c of the solid electrolyte body 141 in electrical contact with the measuring electrode layer connector portion 143a of the measuring electrode layer 143.

As shown in FIG. 2B, subsequently, the metallic cushion member 131 is inserted to the housing 150. Thereafter, the concentration detecting element 140 is inserted to the substantially cylindrical housing 150 until the solid electrolyte engaging portion 144 is caused to rest on the housing engaging portion 151 of the housing 150 via the metallic cushion member 131 being compressed therebetween. Subsequently, the air space AS between the concentration detecting element 140 and the housing 150 is filled with the fixing member 130 including, for instance, the insulating powder 132 such as talc, the insulating powder compact body 133, the insulating sealing member 134 made of ceramic, glass or the like, and the elastic packing member 135 or the like made of elastic material such as rubber or the like.

Next, the metallic cushion member 131 is inserted to the housing 150 as the holding element 130. Thereafter, the concentration detecting element 140 is inserted to the substantially cylindrical housing 150 until the solid electrolyte engaging portion 144 is caused to rest on the housing engaging portion 151 of the housing 150 with the metallic cushion member 131 being compressed therebetween. Subsequently, the air space AS between the concentration detecting element 140 and the housing 150 is filled with the fixing member 130 such as, for instance, the insulating powder 132 such as talc, the insulating powder compact body 133, the insulating sealing member 134 made of such as ceramic, glass or the like, and the elastic packing member 135 or the like made of elastic material such as rubber or the like.

Thereafter, the double-layered cover body 160, comprised of a cover inner shell 161 and a cover body 163, is attached to a leading end of the housing 150 for protecting the leading end portion 141a of the concentration detecting element 140 in an area exposed to measuring gases.

Subsequently, caulking the upper and lower opening end portions 154, 156 as shown by arrows A1, A2 in FIG. 2C, respectively, completes a sub assembly of the detecting unit 10 with the pair of output terminals 111, 121 and the heater electrodes 101, 102 being exposed from the base end of the housing 150 and the output terminals 111, 121 clamping the heater base body 104 as shown in FIG. 2D.

In the steps shown in FIGS. 2A to 2D, the detecting unit 10 can be assembled with all the associated component parts being set out along a single center axis, providing an ease of achieving extremely rationalized production.

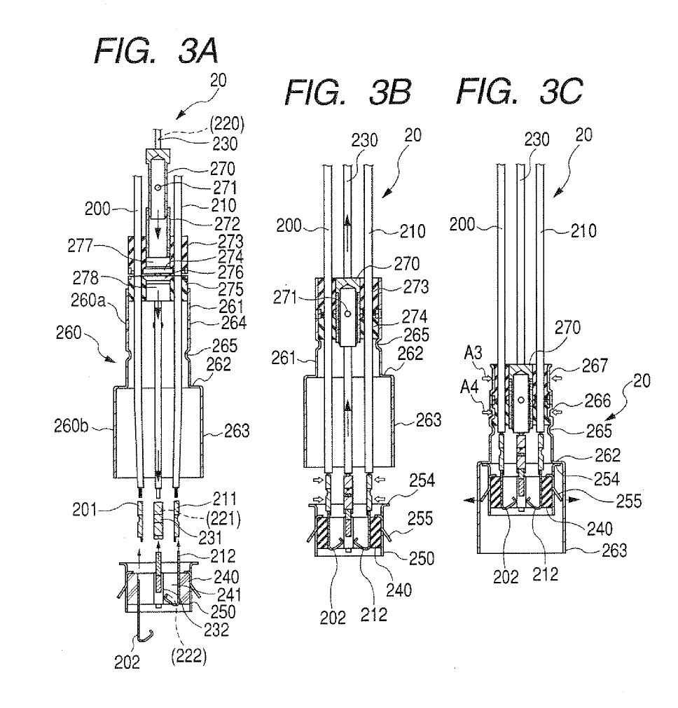

Next, a method of manufacturing the output extracting unit 20 will be described below in detail with reference to FIGS. 3A to 3C in order.

As shown in FIG. 3A, the insulator 240 is prepared by using insulating material such as, for instance, alumina or the like. The insulator 240, formed in a substantially cylindrical body having the plurality of insertion bores 241, is fitted to the insulator holder fitting 250. During such an assembling step, the output extracting terminals 202, 212 and the power conducting terminals 232, 222 are inserted to and fixedly secured to the insulator 240. In addition, the insulator 240, the output extracting terminals 202, 212 and the power conducting terminals 232, 222 will be described later in detail.

In FIG. 3A, further, the casing 260, made of metal such as stainless steel or the like, is formed in the substantially cylindrical sleeve. The casing has a base end portion 260a formed with a small-diameter casing portion 261 and a leading end portion 160b formed with a large-diameter casing portion 261. The annular shoulder 262 is formed at a boundary between the small-diameter casing portion 261 and the large-diameter casing portion 261 in an overall circumferential area or circumferentially spaced multiple positions so as to extend radially inward on a plane substantially perpendicular to the center axis, that is, in a substantially horizontal direction with respect to the center axis. The annular shoulder 262 acts as a casing engagement portion. The small-diameter casing portion 261 has the plural casing venting holes 264 that open radially inward. The small-diameter casing portion 261 has a radially and inwardly extending engaging portion 265 formed in an overall circumferential area or circumferentially spaced multiple areas at positions between the annular shoulder 262 and the venting holes 264.

As shown in FIG. 3A, the pair of signal wires 200, 210 and the pair of power conducting wires 220, 230 are preliminarily inserted to the substantially cylindrical sealing members 273, 275, each made of rubber. Then, the sealing members 273, 275 are inserted to the casing 260 from an upper side of the base end portion 260a. During such inserting step, leading ends of the signal wires 200, 210 and the output extracting terminals 202, 212 are taken out of the casing 260 at a leading end thereof. The signal wires 200, 210 are connected to the output extracting terminals 202, 212 through the connector fittings 201, 211 in press bonding connections, respectively. Likewise, the power conducting terminals 222, 232 and the power conducting wires 220, 230 are connected to each other through the connector fittings 221, 231 in press bonding connections, respectively.

The sealing members 273, 275 are inserted to the small-diameter casing portion 261 until a bottom wall of the sealing member 275 is brought into abutting engagement with the engaging portion 265. The sealing members 273, 275 have filter insertion holes 277, 278 coaxially formed with center axes of the sealing members 273, 275.

The cylindrical, bottomed filter support member 279, formed with plural venting holes 271, is fitted to the water-shedding filter 272, which in turn is inserted to the filter insertion holes 277, 278 formed in the sealing members 273, 275 at the center axes thereof.

With the sealing members 273, 275 placed in such statuses, the casing venting holes 264 are brought into fluid communication with sealing member venting holes 274, 276, formed in the sealing members 273, 275, and support-member venting holes 271 formed in the filter support member 270.

The insulator holder fitting 250, retaining the insulator 240, is inserted to the large-diameter casing portion 263 while pulling the signal wires 200, 210 and the power conducting wires 220, 230 out of a base end of the small-diameter portion 261. This allows the insulator holder fitting 250 to be inserted to the large-diameter casing portion 263 of the casing 260 until a radially extending annular flange 254 of the insulator holder fitting 250 is brought into abutting contact with the casing engaging portion 262 as shown in FIG. 3C. The insulator holder fitting 250 has a plurality of downwardly and obliquely extending fixture segments 255 that engage an inner wall of the large-diameter casing portion 263 of the casing 260 to fixedly retain the insulator holder fitting 250 in the large-diameter casing portion 263.

Subsequently, the small-diameter portion 261 of the casing 260 is caulked at two caulked portions 266, 267 axially spaced from each other with a given distance as indicated by arrows A3, A4, respectively, in FIG. 3C. This allows the sealing members 273, 275, the signal wires 200, 210, the power conducting wires 220, 230, the water-shedding filter 272 and the filter support member 270 to be fixed in place, thereby completing the output extracting unit 20.

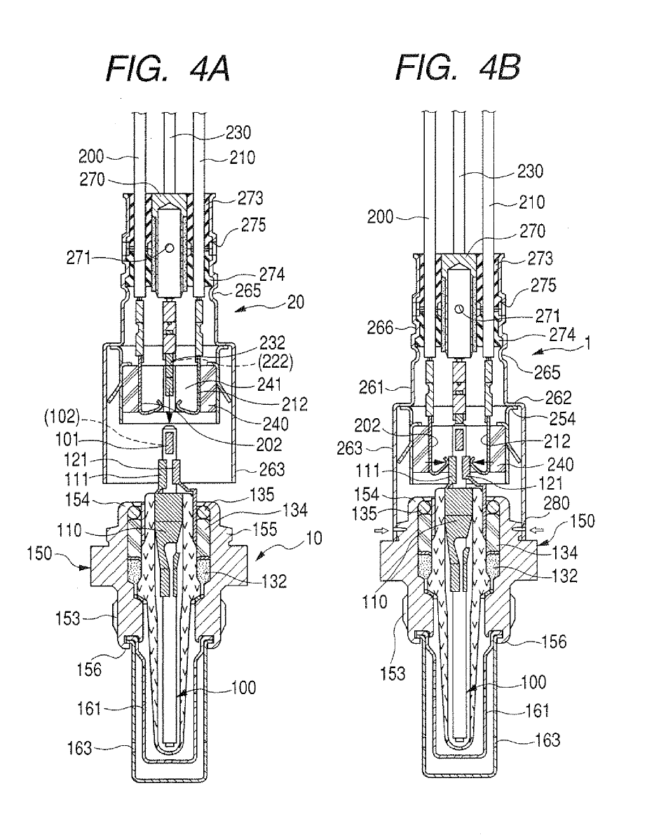

Next, a method of completing the assembling of the gas sensor 1 will be described below in detail with reference to FIGS. 4A and 4B.

As shown in FIGS. 4A and 4B, the boss portion 155 of the housing 150 forming the detecting unit 10 is inserted to the small-diameter portion 263 of the output extracting unit 20. During such an inserting step, the output terminals 111, 121 and the heater 100 are inserted to the insertion bores 241a, 241b, 245 formed in the insulator 240. This causes the output terminals 111, 121 and the output extracting terminals 202, 212 to be brought into electrical connection to each other and the heater electrodes 101, 102 and the power conducting terminals 232, 222 to be brought into electrical connection to each other.

Thereafter, an entire circumference of the boss portion 155 of the housing 150 and a lower end of the large-diameter portion 263 are bonded to each other by a laser welding or the like, thereby completing the gas sensor 1.

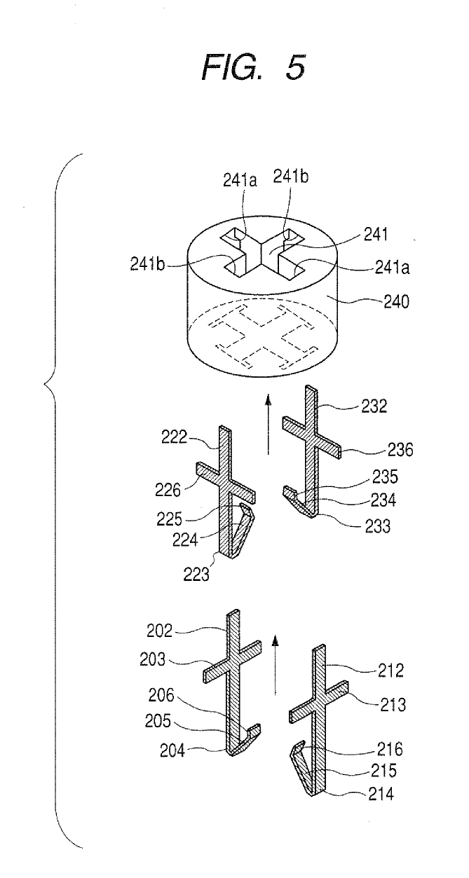

Referring to FIG. 5, description is made of the output extracting terminals 202, 212, the power conducting terminals 222, 232 and the insulator 240.

FIG. 5 is a perspective view showing the output extracting terminals 202, 212, the power conducting terminals 222, 232 and the insulator 240.

The output extracting terminals 202, 212, made of resilient metallic material, are formed in substantially “J”-shapes in cross section. In particular, the output extracting terminals 202, 212 have leading ends formed with radially and inwardly extending bent portions 204, 214, sloped portions 205, 215 inclined toward an axis of the insulator 240 and radially extending inward from the bent portions 204, 214, and abutting portions 206, 216 formed at base ends of the sloped portions 205, 215 and radially bent again to be available to be brought into abutting engagement with the output terminals 111, 121.

Further, the output extracting terminals 202, 212 include laterally jutting out output terminal wings 203, 213 that act as locking parts to be locked when inserted to the insulator 240.

The power conducting terminals 222, 232, made of resilient metallic material, are formed in substantially “U”-shapes in cross section. In particular, the output extracting terminals 222, 232 have leading ends formed with bent portions 223, 233 that extend radially inward in a base end direction, sloped portions 224, 234 inclined toward an axis of the insulator 240 and radially extending inward from the bent portions 223, 233, and abutting portions 225, 235 formed at base ends of the sloped portions 224, 234 and radially bent again to be available to be brought into abutting engagement with the beater terminals 101, 102.

Further, the output extracting terminals 222, 232 include output terminal wings 226, 236 that laterally jut out to act as locking parts to be locked when inserted to the insulator 240.

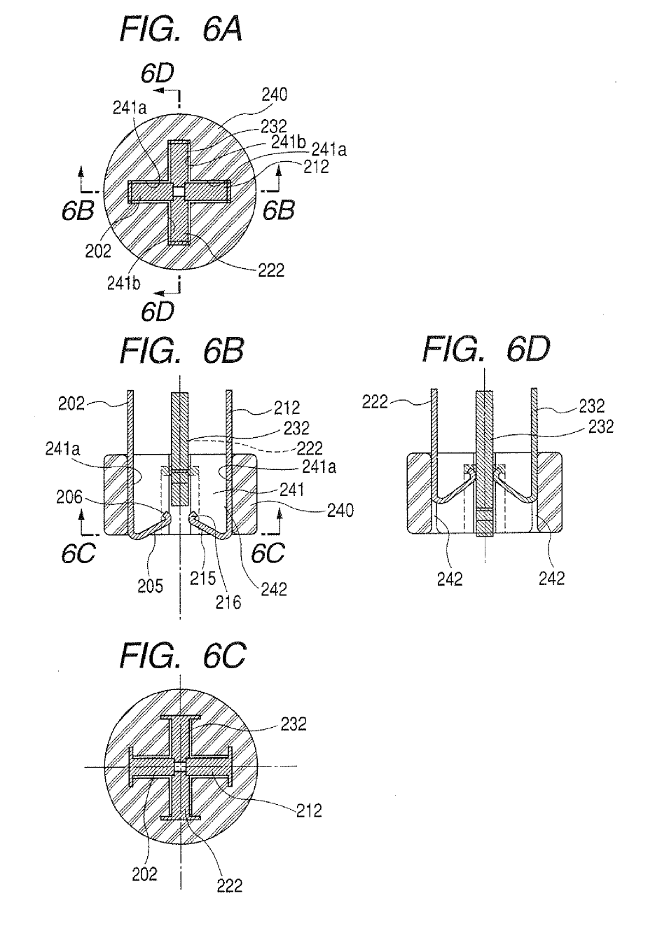

FIG. 6A shows a detail of the insulator 240 with the output terminals 202, 212 and the power conducting terminals 222, 232 held in inserted in fixed states.

As shown in FIG. 6A, the insulator 240 has the substantially cross-shaped heater insertion bore 241 that includes a first pair of axially extending through-holes 241a aligned on one axis and a second pair of axially extending through-holes 241b aligned on the other axis perpendicular to the one axis. The first axially extending through-holes 241a accommodate therein the output extracting terminals 202, 212. Likewise, the second axially extending through-holes 241b accommodate therein the power conducting terminals 222, 232. The first and second axially extending through-holes 241a, 241b have radially indent slit-shaped engaging portions 242, respectively, as shown in FIGS. 6B and 6C.

The output terminal wings 203, 213 of the output terminals 202, 212 and the output terminal wings 226, 236 of the power conducting terminals 222, 232 are inserted to and held in engagement with the slit-shaped engaging portions 242, respectively.

FIG. 6B is a cross-sectional view, taken on line 6B-6B of FIG. 6A, which shows the insulator 240 with the output terminals 202, 212 and the power conducting terminals 222, 232 held in inserted and fixed states.

FIG. 6C is a cross-sectional view, taken on line 6C-6C of FIG. 6A, which shows the insulator 240 with the output terminals 202, 212 and the power conducting terminals 222, 232 held in inserted and fixed states.

FIG. 6D is a cross-sectional view, taken on line 6D-6D of FIG. 6A, which shows the insulator 240 with the output terminals 202, 212 and the power conducting terminals 222, 232 held in inserted and fixed states.

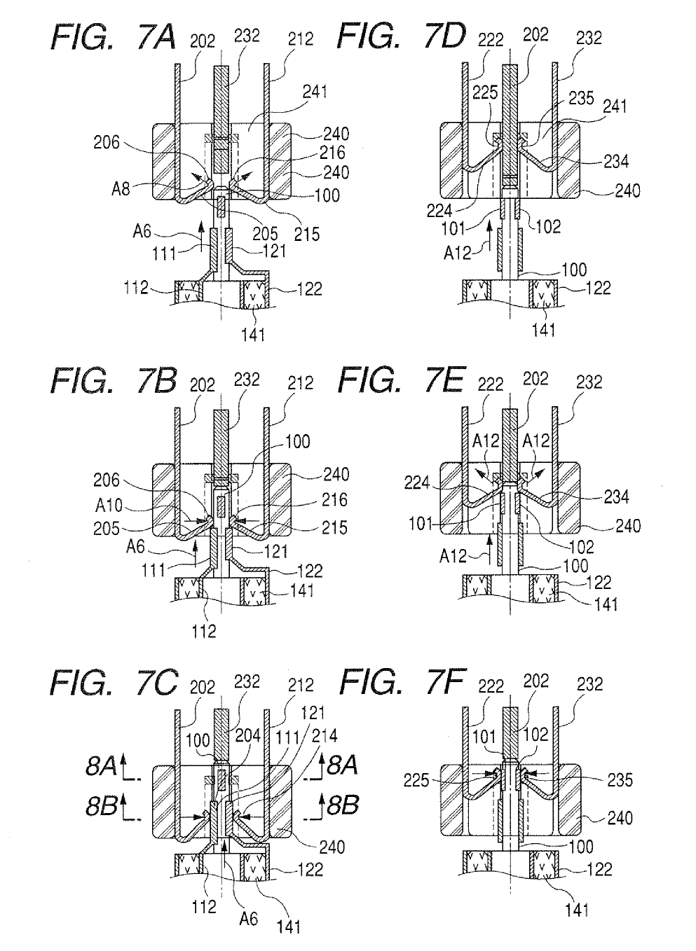

FIGS. 7A to 7C shows positional relationships between the output terminals 111, 121 of the reference electrode fitting 110 and the measuring electrode fitting 120 and the insulator 240 during a process of inserting the heater 100 into the insulator 240. FIGS. 7D to 7F shows positional relationships between the heater electrodes 101, 102 of the heater 100 and the insulator 240 during the process of inserting the heater 100 into the insulator 240.

As shown in FIG. 7A, as the heater 100 moved upward as shown by an arrow A6 for insertion to the insulator 240, a tip of the heater 100 is brought into contact with the sloped portions 205, 215 of the output extracting terminals 202, 212, which are consequently expanded in radially and upwardly outward directions as shown by arrows A8. This allows the heater 100 to be inserted to the insulator 240 with no specific strong resistance.

As shown in FIG. 7B, once the heater 100 is clamped between the sloped portions 205, 215, the heater 100 can move upward in the direction as shown by the arrow A6 with both sides of the heater 100 held in sliding contact with the radially bent abutting portions 206, 216 of the sloped portions 205, 215 due to restoring forces thereof as indicated by arrows A10 in FIG. 7B.

Upon completed movement of the heater 100 with a state inserted to the insulator 240 as shown in FIG. 7C, the output terminals 111, 121 and the output extracting terminals 202, 212 are brought into resilient contact with each other to establish conducting states by means of the abutting portions 206, 216 of the sloped portions 205, 215, respectively, due to the restoring forces as indicated by arrows A10 in FIG. 7C.

Likewise, as shown in FIGS. 7D to 7F, as the heater 100 is inserted to the insulator 240 in an upper direction as shown by an arrow A12 in FIG. 7D, the sloped portions 224, 234 of the power conducting terminals 222, 232 are resiliently flexed. This allows the heater 100 to slidably move in the upper direction A12 between the abutting portions 225, 235 of the sloped portions 224, 234 with no hindrance.

During further upward movement of the heater 100, the abutting portions 225, 235 of the sloped portions 224, 234 are expanded as shown by arrows A12 in FIG. 7E. This permits the output terminals 101, 102 of the heater 100 to be brought into resilient contact in electrical connection with the abutting portions 225, 235 of the sloped portions 224, 234 as shown in FIG. 7F.

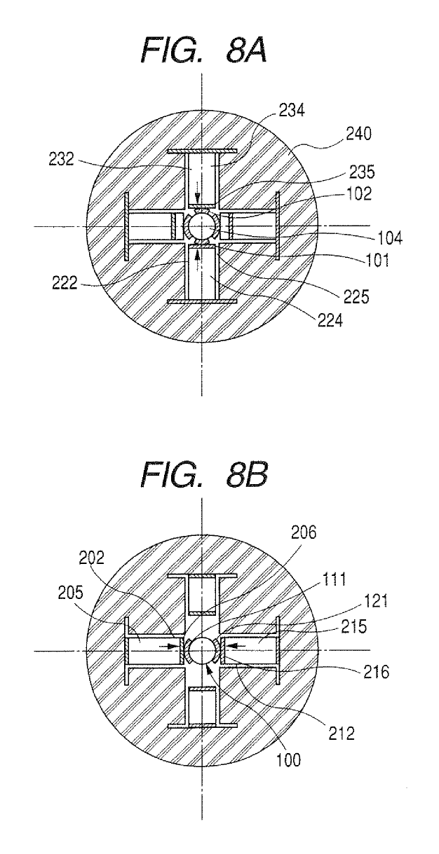

FIG. 8A is a cross-sectional view taken on line 8A-8A of FIG. 7C and FIG. 8A is a cross-sectional view taken on line 8B-8B of FIG. 7C.

As shown in FIG. 8A, the heater electrodes 101, 102, formed on the heater 100, have circular arc-shaped cross sections held in electrical connection with the abutting portions 225, 235 having flat cross sections. Therefore, even if the heater 100 is caused to rotate in the concentration detecting element 140 during assembly in a circumferentially deviated position, the heater electrodes 101, 102 are surely brought into contact with the power conducting terminals 222, 232 each at one point in electrical connection in a highly reliable manner.

As shown in FIG. 8B, the output terminals 111, 121 have circular arc-shaped cross sections convexed toward the abutting portions 206, 216 of the sloped portions 205, 206 of the output extracting terminals 202, 212. Meanwhile, the abutting portions 206, 216 of the sloped portions 205, 206 have flat cross sections. Therefore, even if the mounting positions of the reference electrode fitting 110 or the measuring electrode fitting 120 are caused to circumferentially rotate to be deviated from the concentration detecting element 140, the output terminals 111, 121 and the abutting portions 206, 216 are surely brought into contact with each other and the heater 100 supports concaved surfaces of the output terminals 111, 121. Therefore, pressing forces of the output terminals 111, 121 due to their spring actions are concentrated on the contact points. This allows the output terminals 111, 121 and the output extracting terminals 202, 212 to be electrically connected in a highly reliable manner.

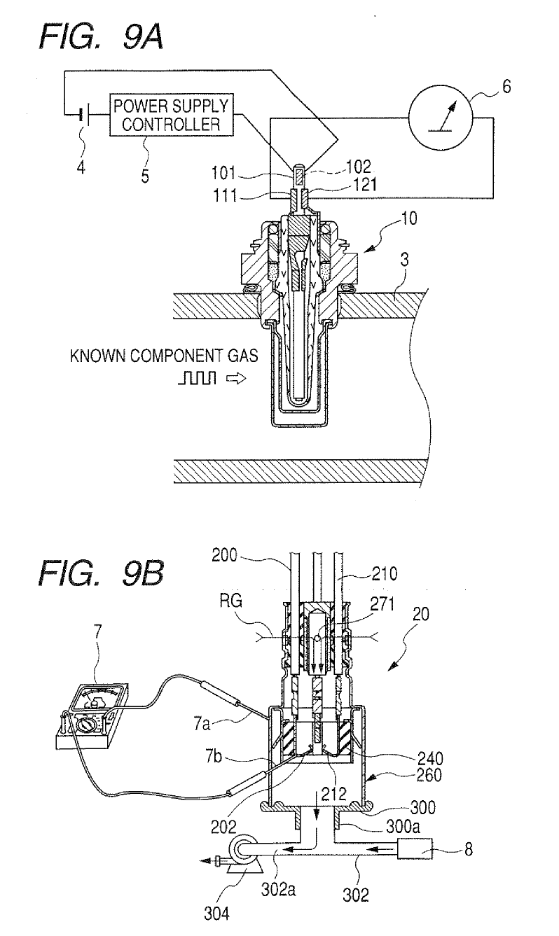

FIGS. 9A and 9B show a method of carrying out the inspection of various units in a midcourse of manufacturing the gas sensor of the present embodiment available to be carried out when implementing the present invention. In particular, FIG. 9A is a conceptual view showing a method of inspecting the detecting unit 10 and FIG. 9B is a conceptual view showing a method of inspecting the output extracting unit 20.

As shown in FIG. 9A, the detecting unit 10 in an assembled state is installed on a measuring gas passage 3, formed in a structure similar to an exhaust gas flow passage, to which known component gases with a specified gas concentration periodically varied is introduced. Under such an installed state, the heater electrodes 101, 102 are electrically connected to an electric power supply 4 via a power-supply controller 5 to receive electric power therefrom. Meanwhile, the output terminals 111, 121 are connected to a detecting unit 6 such as, for instance, a potentiometer for detecting an output of the detecting unit 10. Thus, with electric power supplied to the heater electrodes 101, 102, the potentiometer 6 is able to perform an evaluation on a pulse response of the detecting unit 10.

As shown in FIG. 9B, the casing 260 of the output extracting unit 20 is fixedly placed on a base 300 whose duct 300a is hermetically connected to a pipe 302 having one end 302a, connected to an exhaust unit 304 such as a blower or the like, and the other end connected to a manometer 8. During an evaluation test, reference gas (atmospheric gas) RG is introduced into the casing 260. The manometer 8 performs an evaluation on ventilating property of the casing 260. An insulation meter 7 has one end 7a connected to the casing 260 and the other end connected to the output extracting terminals 202, 212 or the power conducting terminals 222, 232 for measuring insulation properties between the casing 260 and the output extracting terminals 202, 212 or the power conducting terminals 222, 232. This allows a quality of the output extracting unit 20 to be evaluated.

Further, the use of an expedient using the manometer 8 makes it possible to evaluate sealing property of the detecting unit 10.

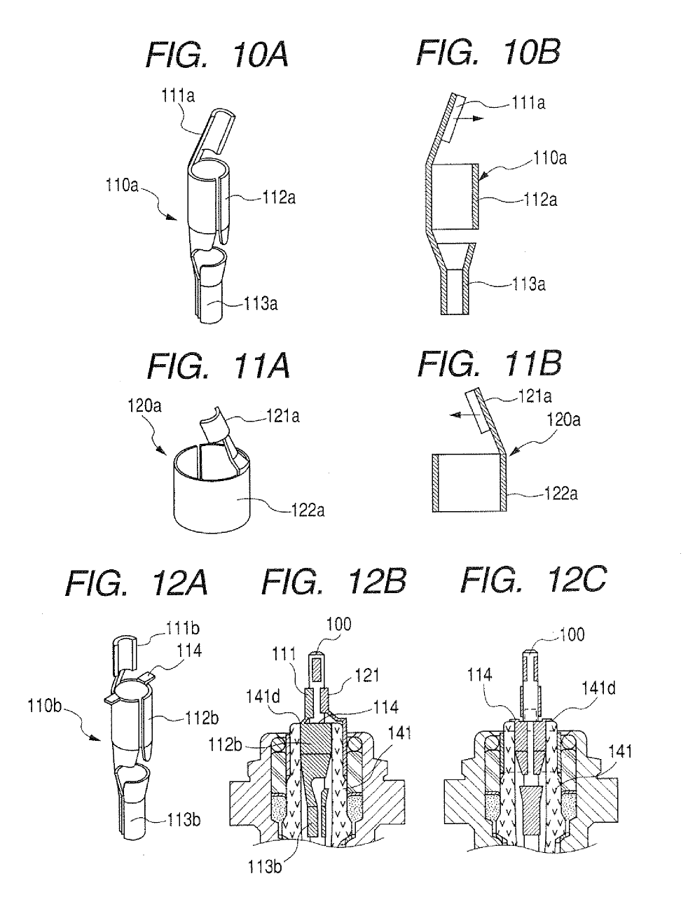

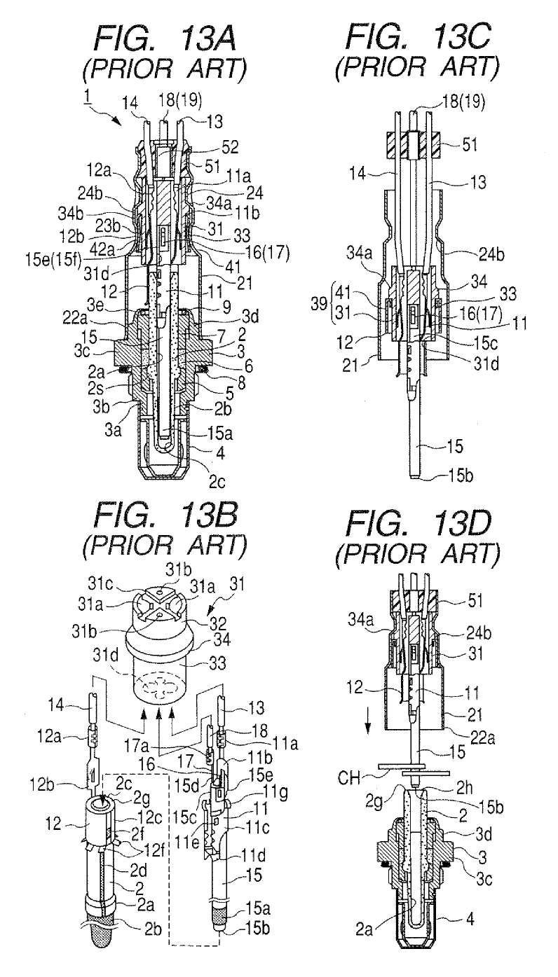

As shown in FIGS. 10A and 10B, the gas sensor 1 may include a modified reference electrode fitting 110a. The reference electrode fitting 110a includes a reference electrode output terminal 111a, a reference electrode connecting portion 112a and a heater clamping portion 113. The reference electrode output terminal 111a is inclined to an axis of the reference electrode connecting portion 112a.

As shown in FIGS. 11A and 11B, likewise, the gas sensor 1 may also include a modified measuring electrode fitting 120a. The measuring electrode fitting 120a includes a measuring electrode output terminal 121a and a measuring electrode connecting portion 122a. The measuring electrode output terminal 121a is inclined to an axis of the measuring electrode connecting portion 122a.

With the reference electrode fitting 110a and the measuring electrode fitting 120a of such structures, the reference electrode output terminal 111a and the measuring electrode output terminal 121a are held in contact with the heater base body 104 with increased resilient forces. This allows the heater 100 to have further increased vibration proof.

As shown in FIGS. 12A to 12C, the gas sensor 1 may include another modified reference electrode fitting 110b. The reference electrode fitting 110b includes a reference electrode output terminal 111b, a reference electrode connecting portion 112b and a heater clamping portion 113b. The reference electrode connecting portion 112b has a base end formed with radially and outwardly extending reference-electrode-terminal engaging portions 114 serving as positioning tabs, respectively. With the reference electrode fitting 110b fitted to the solid electrolyte body 141, reference-electrode-terminal engaging portions 114 are held in abutting engagement with an upper end face 141d of the solid electrolyte body 141. This allows the reference electrode fitting 110b to be easily positioned in fixed place.

While the specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention, which is to be given the fill breadth of the following claims and all equivalents thereof.

While, for instance, the present invention has been described above with reference to the gas sensor in the form of the oxygen concentration sensor including the concentration detecting element having the solid electrolyte body, made of oxygen ion conductive material, which has the inner and outer walls formed with the electrode layers, the present invention may also be preferably applied to a NOx sensor or the like including a measuring section formed with multiple electrode layers and solid electrolyte layers.

Further, the gas sensor of the present invention may suitably adopt a concept of the invention (disclosed in Japanese Patent Application No. 2005-321156 filed by the same inventor on a preceding filing date) related to a ventilating section.

What is claimed is:

1. A cup-shaped gas sensor having a concentration detecting element composed of an ion conductive solid electrolyte body, formed in a bottomed cylindrical structure with a closed leading end, which has an inner wall, formed with a reference electrode layer available to be held in contact with reference gas, and an outer wall, formed with a measuring electrode layer available to be held in contact with measuring gases for detecting a concentration of a specified gas in the measuring gases, the gas sensor comprising:
a detecting unit composed of at least the concentration detecting element, a housing fixedly supporting the concentration detecting element in a measuring gas flow passage, a pair of output terminals comprised of a reference electrode output terminal, extending from the reference electrode layer, and a measuring electrode output terminal, extending from the measuring electrode layer, and a heater, composed of an insulating base body internally having a heating element, which has a pair of heater electrodes formed on a surface of the insulating base body and connected to the heating element for generating a heat when supplied with electric power; and
an output extracting unit including at least a pair of signal wires connectable to an external controller, a pair of output extracting terminals connected to the pair of signal wires, respectively, a pair of power conducting terminals connected to the pair of power conducting wires, an insulator holding the pair of output extracting terminals and the pair of power conducting terminals in insulating capability, an insulator holding the pair of output extracting terminals in insulating capability, a substantially cylindrical casing protecting the insulator, a sealing member disposed in the housing at a base end portion thereof for sealing the pair of signal wires and the pair of power conducting terminals in insulating capability, and a ventilating section introducing atmospheric air to an inside of the casing;
wherein the reference electrode output terminals and the measuring electrode output terminals clamp a part of the insulating base body of the heater as an insulating support member for ensuring an insulation between the reference electrode output terminals and the measuring electrode output terminals;
wherein the insulator has heater insertion bores within which the output terminals and the output extracting terminals are electrically conducted to each other while the heater electrode and the power conducting terminal are electrically conducted to each other; and
wherein the detecting unit and the output extracting unit are united to each other.

2. The gas sensor according to claim 1, wherein:
the reference electrode output terminal and the measuring electrode output terminal have concaved walls, formed in circular-arc shapes in cross section, respectively, which are held in tight contact with a side periphery of the insulating base body of the heater.

3. The gas sensor according to claim 1, wherein:
the output extracting terminals include spring terminals, each made of resilient metallic material and formed in a substantially “J”-shape configuration, which are resiliently held in electrical contact with the output terminals, respectively.

4. The gas sensor according to claim 1, wherein:
the power conducting terminals include spring terminals, each made of resilient metallic material and formed in a substantially “J”-shape configuration, which are resiliently held in electrical contact with the heater electrodes, respectively.

5. The gas sensor according to claim 2, wherein:
the concaved wall of the reference electrode output terminal is inclined toward an axis of the insulating base body.

6. The gas sensor according to claim 2, wherein:
the concaved wall of the measuring electrode output terminal is inclined toward an axis of the insulating base body.

7. The gas sensor according to claim 2, wherein:
the reference electrode output terminal is integrally formed with a reference electrode connecting portion, held in electrical contact with the reference electrode layer, which has a plurality of positioning portions held in contact with the solid electrolyte body to allow the reference electrode connecting portion to be positioned in a fixed place.

8. A method of manufacturing a cup-shaped gas sensor having a concentration detecting element composed of an ion conductive solid electrolyte body, formed in a bottomed cylindrical structure with a closed leading end, which has an inner wall, formed with a reference electrode layer available to be held in contact with reference gas, and an outer wall, formed with a measuring electrode layer available to be held in contact with measuring gases for detecting a concentration of a specified gas in the measuring gases, the method comprising the steps of:
forming a detecting unit including the steps of holding a heater, operative to generate a heat when supplied with electric power, in the concentration detecting unit via a reference electrode fitting having a reference electrode output terminal, a reference electrode connecting portion and a heater clamping portion, mounting a measuring electrode fitting having a measuring electrode output terminal and a measuring electrode connecting portion onto the measuring electrode layer, inserting the concentration detecting element into a substantially cylindrical housing via a fixing member for thereby forming the detecting unit including at least a pair of output terminals, composed of the reference electrode output terminal and the measuring electrode output terminal, the heater and the housing wherein the output terminals and a pair of heater electrodes, formed on a surface of the heater, are exposed to an upper area of the housing and the pair of output terminals clamp the heater;
forming an output extracting unit including the steps of mounting a pair of output extracting terminals and a pair of power conducting terminals into an insulator, connecting a pair of signal wires to the pair of output terminals, respectively, connecting a pair of power conducting wires to the pair of power conducting terminals, respectively, inserting the pair of signal wires and the pair of power conducting wires into the insulator in a plurality of insertion bores formed therein, and accommodating the insulator in a substantially cylindrical casing for thereby forming the output extracting unit including at least the signal wires, the power conducting wires, the output extracting terminals, the power conducting terminals, the insulator and the casing;
forming output extracting terminals including the step of forming the output extracting terminals and the power conducting terminals in spring-like terminals formed in substantially “J”-shaped configurations having flat shapes in cross section using a resilient metallic material; and
assembling the gas sensor including the steps of inserting the detecting unit into the output extracting unit to cause the output terminals and the output extracting terminals and the heater electrodes and the power conducting terminals to be conducted to each other within the insertion bores formed in the insulator for thereby completing an assembly of the gas sensor.

9. The method of manufacturing a cup-shaped gas sensor according to claim 8, further comprising the step of:
forming the output terminals including the steps of making the pair of output terminals using a resilient metallic material, and forming the output terminals in concaved walls, held in abutting contact with a surface of the beater, each of which has a circular-arc shape in cross section facing the heater.
